(19) United States
(12) Patent Application Publication
(10) Pub. No.: US 2014/0015515 A1
(43) Pub. Date: Jan. 16, 2014

(54) Shunt Resistance Type Current Sensor

(71) Applicant: YAZAKI CORPORATION, Tokyo (JP)

(72) Inventor: Takashi Satou, Susono-Shi (JP)

(73) Assignee: YAZAKI CORPORATION, Tokyo (JP)

(21) Appl. No.: 14/032,423

(22) Filed: Sep. 20, 2013

Related U.S. Application Data
(63) Continuation of application No. PCT/JP2012/059947, filed on Apr. 5, 2012.

(30) Foreign Application Priority Data
Apr. 5, 2011 (JP) 2011-083706

(51) Int. Cl. G01R 1/20

(52) U.S. Cl. CPC G01R 1/203
USPC 324/126

(57) ABSTRACT

A shunt resistance type current sensor includes a bus bar which has a flat plate shape, a circuit board which is provided on the bus bar, connecting terminal portions which are extended from the bus bar, and are electrically connected to the circuit board, and a voltage detecting section which is provided on the circuit board and detects a voltage value applied to the circuit board through the connecting terminal portions for detecting the amplitude of a measured electric current flowing through the bus bar. The connecting terminal portions are formed in pair by being protruded towards each other, and each of the connecting terminal portions is a cantilever that rises from a flat plate part of the bus bar.

### CROSS REFERENCE TO RELATED APPLICATIONS

This application is a continuation of PCT application No. PCT/JP2012/059947, which was filed on Apr. 2015, 2012 based on Japanese Patent Application (No. P2012011-083706) filed on Apr. 5, 2011, the contents of which are incorporated herein by reference.

### BACKGROUND OF THE INVENTION

1. Field of the Invention

The present invention relates to a shunt resistance type current sensor.

2. Description of the Related Art

Conventionally, to measure a pulse electric current or a large alternating electric current, a shunt resistance type current sensor is proposed in which a measured electric current flows through a shunt resistance whose resistance value is known, and a voltage drop generated in the shunt resistance is measured. When the shunt resistance type current sensor measures the voltage drop, it is necessary to connect the shunt resistance to a circuit board on which a voltage detection IC for measuring the voltage drop is installed. When the shunt resistance is a bus bar, it is necessary to connect the bus bar and the circuit board.

However, because the thermal expansion coefficient of the bus bar is different from that of the circuit board, there is stress on the bus bar and the circuit board due to the thermal expansion difference, and there is a problem of durability. Thus, a shunt resistance type current sensor which addresses the durability problem due to the thermal expansion difference is proposed (referring to JP-A-2005-188972 and JP-A-2005-188973).

### SUMMARY OF THE INVENTION

However, because the shunt resistance type current sensors described in JP-A-2005-188972 and JP-A-2005-188973 use an expensive flexible wiring board (circuit board) which has a high flexibility, and pin-shaped connecting members are necessary, there is room for improvement in terms of cost.

The present invention is accomplished to solve the above problems, and an object of the invention is to provide a shunt resistance type current sensor so that the durability problem due to the thermal expansion difference is tackled, and improvement in terms of cost can be made.

In order to achieve the above object, according to the present invention, there is provided a shunt resistance type current sensor, comprising

a bus bar which has a flat plate shape;

a circuit board which is provided on the bus bar;

connecting terminal portions which are extended from the bus bar, and are electrically connected to the circuit board; and

a voltage detecting section which is provided on the circuit board and detects a voltage value applied to the circuit board through the connecting terminal portions for detecting the amplitude of a measured electric current flowing through the bus bar,

wherein the connecting terminal portions are formed in pair by being protruded towards each other, and each of the connecting terminal portions is a cantilever that rises from a flat plate part of the bus bar.

According to the shunt resistance type current sensor of the present invention, the connecting terminal portions are extended from the bus bar and are electrically connected with the circuit board. Further, each of the connecting terminal portions is a cantilever that rises from the flat plate part of the bus bar. Therefore, even if stress occurs due to the thermal expansion difference between the bus bar and the circuit board, the stress is relieved by elasticity of the connecting terminal portions which are formed to be cantilevers. Further, because the connecting terminal portions are formed in pair by being protruded towards each other, the distance in which the stress occurs can be shortened and the stress can be decreased. Thus, the durability problem due to the thermal expansion difference can be addressed. Further, it is not necessary to require the circuit board to be a flexible circuit board which has high flexibility but is expensive. Besides, pin-shaped connecting members are not necessary because the connecting terminal portions are formed so that parts of the connecting terminal portions rise from the flat plate part of the bus bar. Thus, improvement in terms of cost can be made.

For example, the size of each of he connecting terminal portions in a widthwise direction thereof is smaller than the size of each of the connecting terminal portions in a lengthwise direction thereof.

According to the shunt resistance type current sensor, because the size of each of the connecting terminal portions in the widthwise direction is smaller than the size in the lengthwise direction, the connecting terminal portions are narrow and are easy to be flexed, and the stress is easy to be relieved. Further, because the connecting terminal portions are narrow, when the connecting terminal portions 40 are electrically connected with the circuit board by being soldered, the soldering for which it is hard to dissipate heat can be performed easily.

For example, the shunt resistance type current sensor further includes a temperature detecting section which detects the temperature near the bus bar, and the voltage detecting section makes voltage revision based on a detection result from the temperature detecting section.

According to the shunt resistance type current sensor, the temperature detecting section which detects the temperature near the bus bar is further included, and the voltage detecting section makes voltage revision based on the detection results from the temperature detecting section. Therefore, a wrong result due to resistance change due to the influence of temperature can be prevented from being obtained.

For example, the bus bar is a battery terminal.

According to the shunt resistance type current sensor, the bus bar is a battery terminal. Here, copper alloy is used for the battery terminal, and has a bigger resistance change due to temperature than the materials (for example, manganin) used for shunt resistances that have a smaller resistance change due to temperature. However, to make temperature revision, in the shunt resistance type current sensor used for the battery terminal, more effective temperature revision can be made.

According to the present invention, a shunt resistance type current sensor can be provided so that the durability problem due to the thermal expansion difference is tackled, and improvement in terms of cost is made.

### BRIEF DESCRIPTION OF THE DRAWINGS

FIG. 1 is a top view which shows an example of a conventional shunt resistance type current sensor.

FIG. 2 is a top view which shows a bus bar of a shunt resistance type current sensor according to an embodiment of the invention.

FIG. 3 is an A-A sectional view in FIG. 2 which shows the bus bar of the shunt resistance type current sensor according to the embodiment.

FIG. 4 is a top view of the shunt resistance type current sensor according to the present embodiment of the invention.

FIG. 5 is a side view of the shunt resistance type current sensor according to the present embodiment.

FIG. 6 is a figure which shows the use of the shunt resistance type current sensor according to the present embodiment.

FIG. 7 is a top view of the bus bar which shows operations of the shunt resistance type current sensor according to the present embodiment.

### DETAILED DESCRIPTION OF THE EXEMPLARY EMBODIMENTS

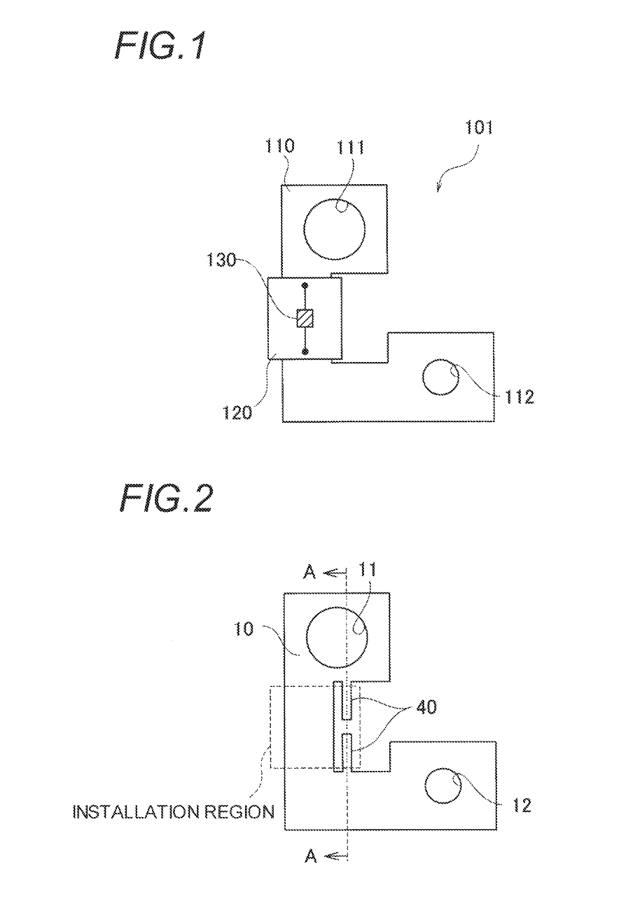

Next, before a preferred embodiment of the present invention is described based on the figures, the thermal expansion difference of a shunt resistance type current sensor is described in detail. FIG. 1 is a top view which shows an example of a conventional shunt resistance type current sensor. The shunt resistance type current sensor 101 shown in FIG. 1 is used as a battery terminal, and includes a bus bar 110, a circuit board 120 and voltage detection IC 130.

The bus bar 110 is a generally flat plate-shaped conductive member, and is made of, for example, cupromanganese alloy or copper nickel alloy. The bus bar 110 is formed to have a desired shape by press mounding a flat plate-shaped steel material. The bus bar 110 serves as a shunt resistance to make a measured electric current to flow.

In more detail, the bus bar 110 is formed to be generally L-shaped, and through holes 111 and 112 are formed at the ends of the L shape, respectively. Among them, one through hole 111 functions as a hole for a battery post, and the other through hole 112 functions as a hole for a fixing screw of a wire harness.

The circuit board 120 is installed on the middle part of the bus bar 110, and is electrically connected to the bus bar 110 by connecting pins. The voltage detection IC 130 detects a voltage value that is applied to the circuit board 120 to detect the magnitude of the measured electric current which flows through the bus bar 110. Based on the voltage value which is detected by the voltage detection IC 130, a voltage drop which is generated across the bus bar 110 is measured.

Here, the material of the bus bar 110 is different from that of the circuit board 120. Therefore, their thermal expansion coefficients are different. As an example, at 20° C., the linear expansion coefficient of the bus bar 110 is 16.5*10⁻⁶ [1/K], and the linear expansion coefficient of the circuit board 120 is 16.0*10⁻⁶ [1/K]. When temperature increases, the bus bar 110 becomes longer. Thus, stress occurs at the connecting pins which are the electrically connecting parts of the bus bar 110 and the circuit board 120, and damages may be caused.

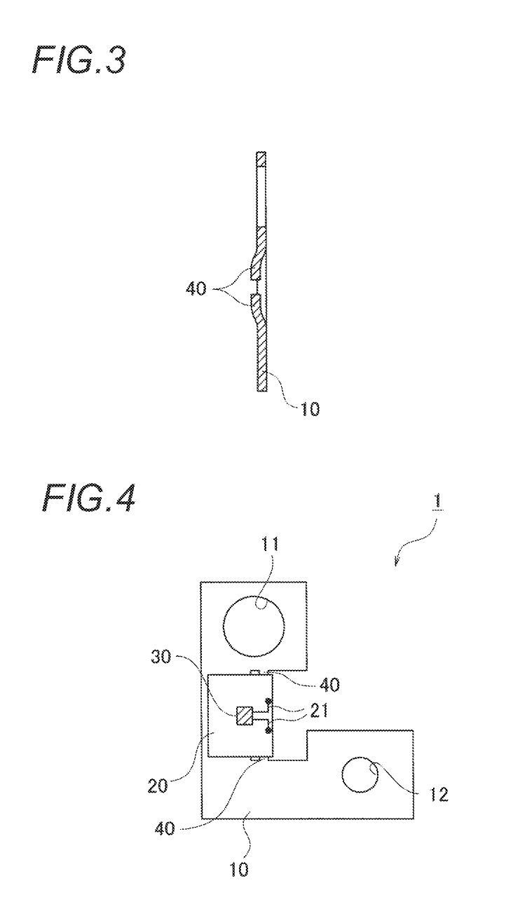

FIG. 2 is a top view which shows a bus bar of a shunt resistance type current sensor according to an embodiment of the present invention, and FIG. 3 is an A-A sectional view in FIG. 2 which shows the bus bar of the shunt resistance type current sensor according to the embodiment of the present invention. The shunt resistance type current sensor 1 shown in these figures includes connecting terminal portions 40. Because the bus bar 10, the circuit board 20 and the voltage detection IC 30 shown in FIG. 2 are similar to those shown in FIG. 1, their descriptions are omitted in the following.

The connecting terminal portions 40 are extended from the bus bar 10 and are formed of the same material as that of the bus bar 10. In other words, the bus bar 10 and the connecting terminal portions 40 are simultaneously formed by press mounding a flat plate-shaped steel material. The connecting terminal portions 40 are formed by being extended from the bus bar 10 towards inside of the installation region of the circuit board 20 in the bus bar 10.

In the embodiment, the connecting terminal portions 40 are formed in pair by being protruded towards each other, and each of the connecting terminal portions 40 is a cantilever that rises from the flat plate part of the bus bar 10. The connecting terminal portions 40 have such a structure that the free ends of the connecting terminal portions 40 are electrically connected to the circuit board 20 by being soldered. As shown in FIG. 2, the size of each of the connecting terminal portions 40 in the widthwise direction is smaller than the size in the lengthwise direction.

FIG. 4 is a top view of the shunt resistance type current sensor 1 according to the present embodiment. As shown in FIG. 4, a circuit pattern 21 is formed on the circuit board 20. The voltage detection IC 30 is installed on the circuit pattern 21. The ends of the circuit pattern 21 are electrically connected to the free ends of the above described connecting terminal portions 40. Therefore, the voltage detection IC 30 detects a voltage value which is applied across the circuit board 20, and the magnitude of the measured current which flows through the bus bar 10 is detected from the voltage drop.

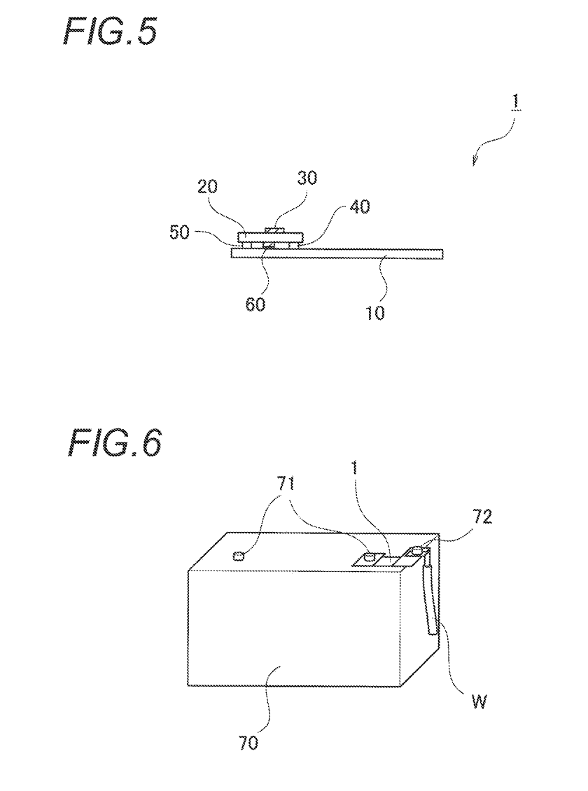

FIG. 5 is a side view of the shunt resistance type current sensor 1 according to the present embodiment. As shown in FIG. 5, the shunt resistance type current sensor 1 further includes a spacer 50 and a temperature sensor (temperature detecting section) 60.

The spacer 50 is located between the bus bar 10 and the circuit board 20. Because the connecting terminal portions 40 rise from the flat plate part of the bus bar 10, the circuit board 20 locates slightly higher than the bus bar 10. Therefore, since the spacer 50 is located at an area opposite to the connecting terminal portions 40 within the installation region of the circuit board 20, the height difference is compensated.

The temperature sensor 60 is provided on the surface of the circuit board 20 opposite to the installing surface of the voltage detection IC 30, and is located near the bus bar 10. Therefore, the temperature sensor 60 detects a temperature near the bus bar 10.

In the embodiment, the voltage detection IC 30 makes voltage revision based on detection results from the temperature sensor 60. In other words, the voltage detection IC 30 makes voltage revision based on the temperature results so that a wrong current value influenced by resistance change due to temperature change will not be detected.

FIG. 6 is a figure which shows the use of the shunt resistance type current sensor 1 according to the present embodiment. As shown in FIG. 6, the bus bar 10 of the shunt resistance type current sensor 1 according to the present embodiment is used as a battery terminal. For this purpose, the through hole 11 of the bus bar 10 is connected to a battery post 71 of a battery 70, and the other through hole 12 of the bus bar 10 is connected to a wire harness W through a fixing screw 72 of the wire harness.

Here, when the bus bar 10 is used as the battery terminal, copper alloy is used for the bus bar 10, and has a bigger resistance change due to temperature than other materials (for example, manganin) used for shunt resistances that have a smaller resistance change due to temperature. However, in order to make enough temperature revision, more effective temperature revision can be made in the shunt resistance type current sensor 1 used as the battery terminal.

Next, operations of the shunt resistance type current sensor 1 according to the present embodiment are described. First, it is assumed that both of the bus bar 10 and the circuit board 20 thermally expand due to the influence of heat. At this time, because the material of the circuit board 20 is different from that of the bus bar 10, the expansion coefficients are also assumed to be different. Therefore, stress occurs due to the difference between the expansion coefficients. The connecting parts (that is, the soldered parts) where the bus bar 10 and the circuit board 20 are electrically connected are damaged, and it is possible that the electrical connection may be broken.

However, the shunt resistance type current sensor 1 according to the present embodiment includes the connecting terminal portions 40. Each of the connecting terminal portions 40 is a cantilever that rises from the flat plate part of the bus bar 10. Due to this, the stress is relieved by the elasticity of the connecting terminal portions 40. Thus, the connecting parts can be prevented from being damaged by the stress.

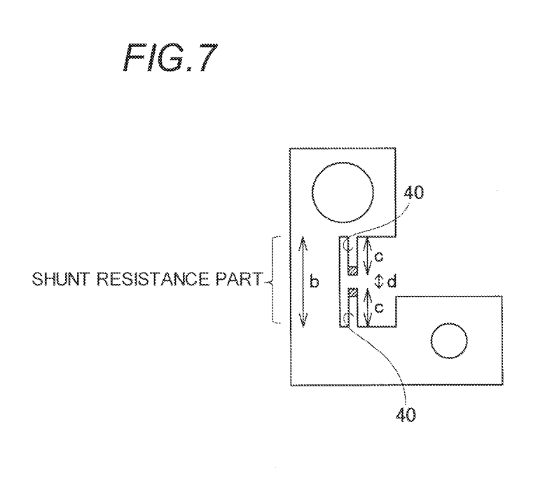

In particular, the connecting terminal portions 40 are formed in pair by being protruded towards each other. FIG. 7 is a top view of the bus bar 10 which shows operations of the shunt resistance type current sensor 1 according to the present embodiment. When the connecting terminal portions 40 are not included, stress occurs in the length h of the shunt resistance part. In contrast, if the length of each of the connecting terminal portions 40 is c, stress will occur in a distance d=b−2c which is the distance between the pair of connecting terminal portions 40 that are protruded towards each other. In other words, since the distance in which the stress occurs is shortened, the stress itself can be smaller.

Thus, the damage of the connecting parts can be prevented. Because the damage of the connecting parts can be prevented, it is not necessary to require the circuit board 20 to be a flexible circuit board which has high flexibility but is expensive. Besides, because the connecting terminal portions 40 are formed to rise from he flat plate part of the bus bar 10, the connecting members of a pin shape are not necessary.

Further, because the size of the connecting terminal portions 40 in the widthwise direction is smaller than the size of the connecting terminal portions 40 in the lengthwise direction, the connecting terminal portions 40 are narrow, it is easier to relieve stress, and the damage of the connecting parts can be further prevented. Because the connecting terminal portions 40 are narrow, when the connecting terminal portions 40 are electrically connected with the circuit board 20 by being soldered, the soldering for which it is hard to dissipate heat can be performed easily.

In addition, because the connecting terminal portions 40 are higher than the flat plate of the bus bar 10, the contact of the bus bar 10 and the circuit board 20 is avoided.

In this way, according to the shunt resistance type current sensor 1 of the present embodiment, the connecting terminal portions 40 are extended from the bus bar 10 in the installation region of the circuit board 20 in the bus bar 10, and are electrically connected to the circuit board 20. Each of the connecting terminal portions 40 is a cantilever that rises from the flat plate part of the bus bar 10. Therefore, even if stress occurs due to the thermal expansion difference between the bus bar 10 and the circuit board 20, the stress is relieved by elasticity of the connecting terminal portions 40 which are formed to be cantilevers. Further, because the connecting terminal portions 40 are formed in pair by being protruded towards each other, the distance in which the stress occurs can be shortened and the stress can be decreased. Thus, the durability problem due to the thermal expansion difference can be addressed. Further, it is not necessary to require the circuit board 20 to be a flexible circuit board which has high flexibility but is expensive. Besides, pin-shaped connecting members are not necessary because the connecting terminal portions 40 are formed so that parts of the connecting terminal portions 40 rise from the flat plate part of the bus bar 10. Thus, improvement in terms of cost can be made.

In addition, because the size of each of the connecting terminal portions 40 in the widthwise direction is smaller than the size in the lengthwise direction, the connecting terminal portions 40 are narrow and are easy to be flexed, and the stress is easy to be relieved. Because the connecting terminal portions 40 are narrow, when the connecting terminal portions 40 are electrically connected with the circuit board 20 by being soldered, the soldering for which it is hard to dissipate heat can be performed easily.

Further, the temperature sensor 60 which detects the temperature near the bus bar 10 is further included, and the voltage detection IC 30 makes voltage revision based on the detection results from the temperature sensor 60. Therefore, a wrong result due to resistance change due to the influence of temperature can be prevented from being obtained.

Further, the bus bar 10 is a battery terminal. Here, copper alloy is used for the battery terminal, and has a bigger resistance change due to temperature than the materials (for example, manganin) used for shunt resistances that have a smaller resistance change due to temperature. However, to make temperature revision, in the shunt resistance type current sensor 1 used for the battery terminal, more effective temperature revision can be made.

Although the invention has been described based on the embodiment as above, the invention is not limited to the above embodiment, and modifications may be made without departing from the scope and spirit of the invention.

For example, in the shunt resistance type current sensor 1 according to the present embodiment, the connecting terminal portions 40 are not limited to the shape according to the embodiment. For example, the connecting terminal portions 40 in the embodiment have a straight shape, but the shape of the connecting terminal portions 40 is not limited to this. It is also possible that the connecting terminal portions 40 have a curved shape. Further, it is also possible that a notch is formed in a part of the connecting terminal portions 40 which have a straight or curved shape. Further, it is also possible that the width of the connecting terminal portions 40 is not constant.

The present invention can provide a shunt resistance type current sensor so that the durability problem due to the thermal expansion difference is tackled, and improvement in terms of cost can be made.

What is claimed is:

1. A shunt resistance type current sensor, comprising
a bus bar which has a flat plate shape;
a circuit board which is provided on the bus bar;
connecting terminal portions which are extended from the bus bar and are formed of the same material as that of the bus bar, and are electrically connected to the circuit board; and
a voltage detecting section which is provided on the circuit board and detects a voltage value applied to the circuit board through the connecting terminal portions for detecting the amplitude of a measured electric current flowing through the bus bar,
wherein the connecting terminal portions are formed in pair by being protruded towards each other, and each of the connecting terminal portions is a cantilever that rises from a flat plate part of the bus bar.

2. The shunt resistance type current sensor according to claim 1, wherein the size of each of the connecting terminal portions in a widthwise direction thereof is smaller than the size of each of the connecting terminal portions in a lengthwise direction thereof.

3. The shunt resistance type current sensor according to claim 1, further comprising:
a temperature detecting section which detects the temperature near the bus bar,
wherein he voltage detecting section makes voltage revision based on a detection result from the temperature detecting section.

4. The shunt resistance type current sensor according to claim 1, wherein the bus bar is a battery terminal.
